(19) United States
(12) Patent Application Publication
(10) Pub. No.: US 2009/0050954 A1
(43) Pub. Date: Feb. 26, 2009

(54) Non-volatile memory device including charge trap layer and method of manufacturing the same

(75) Inventors: Sang-moo Choi, Yongin-si (KR); Kwang-soo Seol, Suwon-si (KR); Sang-jin Park, Pyeongtaek-si (KR); Jung-hun Sung, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/071,351

(22) Filed: Feb. 20, 2008

(30) Foreign Application Priority Data
Aug. 22, 2007 (KR) 10-2007-0084600

(51) Int. Cl. H01L 29/792; H01L 21/28

(52) U.S. Cl. 257/324; 438/591; 257/E29.309; 257/E21.18

(57) ABSTRACT

Provided are a non-volatile memory device and a method of manufacturing the non-volatile memory device. The non-volatile memory device includes a charge trap layer having a crystalline material. In the method, a tunneling insulating layer is formed on a substrate, and a crystalline charge trap layer is formed on the tunneling insulating layer.

### CROSS-REFERENCE TO RELATED PATENT APPLICATION

This application claims the benefit of Korean Patent Application No. 10-2007-0084600, filed on Aug. 22, 2007, in the Korean Intellectual Property Office, the disclosure of which is incorporated herein in its entirety by reference.

### BACKGROUND OF THE INVENTION

1. Field of the Invention

The present invention relates to a non-volatile memory device and a method of manufacturing the same, and more particularly, to a non-volatile memory device including a charge trap layer and a method of manufacturing the non-volatile memory device.

2. Description of the Related Art

Non-volatile memory devices are semiconductor memory devices that can retain data even when electric power is cut off. Examples of non-volatile memory devices include flash memory devices.

NAND (not and) flash memory devices, which are currently in widespread use as high-capacity non-volatile memory devices, have a floating gate type flash memory sells. In the floating gate structure, a floating gate for storaging electric charges and a control gate for controlling the floating gate are sequentially formed to form a memory cell.

In line with the requirements for high-capacity and small-sized flash memory devices, many efforts have been made to reduce the size of memory cells of a flash memory device and the vertical height of a floating gate in accordance with the size reduction of the memory cells.

A charge-trap semiconductor memory device having a silicon-oxide-nitride-oxide-semiconductor (SONOS) structure has been proposed to efficiently reduce the vertical height of memory cells while maintaining the characteristics of the memory cells such as long retention of stored data. In the SONOS structure of the charge-trap semiconductor memory device, a silicon nitride (Si₃N₄) layer is formed to store electric charges instead of a floating gate.

Such a SONOS memory device has a basic structure as follows. A first silicon oxide (SiO₂) layer is formed as a tunneling insulating layer on a semiconductor substrate between source and drain regions of the semiconductor substrate. That is, the first silicon oxide layer is formed on a channel region of the semiconductor substrate with both sides of the first silicon oxide layer being in contact with the source and drain regions of the semiconductor substrate. The first silicon oxide layer is formed for tunneling charge carriers. A silicon nitride (Si₃N₄) layer is formed on the first silicon oxide layer as a charge trap layer. The silicon nitride layer is a material layer in which data are substantially stored. Charge carriers passing through the first silicon oxide layer by tunneling are trapped in the silicon nitride layer. A second silicon oxide layer is formed on the silicon nitride layer as a blocking insulating layer for preventing charge carriers trapped in the silicon nitride layer from moving upward. A gate electrode is formed on the second silicon oxide layer.

In a charge-trap memory device, instead of a floating gate, a charge trap layer is formed to store information by trapping charge carriers. Basically, the charge-trap memory device includes a gate electrode, a blocking oxide layer, the charge trap layer, a tunneling oxide layer, and a silicon substrate. The charge trap layer can be formed of silicon, metal nanodots, or a high-permittivity (high-k) insulation material such as HfO₂, ZrO₂, and Al₂O₃. For example, the charge trap layer can be a silicon nitride layer. Generally, the charge trap layer is formed of an amorphous material.

When an amorphous silicon nitride layer is used as a charge trap layer of a charge-trap memory device, the charge-trap memory device can operate unreliably due to an extended band tail of the amorphous silicon nitride. Due to the extended band tail, charge carriers trapped at a defect energy level can be easily released. Furthermore, the operating speed of the charge-trap memory device decreases since charge carriers injected in writing/erasing operations move slowly due to the extended band tail. Although other materials can be used for forming the charge trap layer instead of the amorphous silicon nitride, these problems may also occur if the materials are amorphous.

### SUMMARY OF THE INVENTION

The present invention provides a non-volatile memory device including a charge trap layer formed of a crystalline material instead of an amorphous material in order to prevent charge leakage and a decrease in operating speed caused by an extended band tail, and a method of manufacturing the non-volatile memory device.

The non-volatile memory device of the present invention includes a substrate; and a gate structure formed on the substrate and comprising a charge trap layer, the charge trap layer comprising a crystalline material.

The gate structure may further include a tunneling insulating layer under the charge trap layer, a blocking insulating layer formed on the charge trap layer; and a gate electrode formed on the blocking insulating layer.

The device may further include first and second impurity regions formed in the substrate in contact with the tunneling insulating layer.

The substrate may be a silicon substrate, the tunneling insulating layer may be a silicon oxide layer, the blocking insulating layer may be an aluminum oxide layer, and the gate electrode may be a metal layer.

The gate electrode may include a TaN layer.

The charge trap layer may include a crystalline silicon nitride.

Here, the crystalline silicon nitride may have a silicon/nitrogen composition ratio in the range of 0.75≦x/y≦0.9, where x denotes silicon content, and y denotes nitrogen content.

A method of manufacturing a non-volatile memory device includes forming a tunneling insulating layer on a substrate, and forming a crystalline charge trap layer on the tunneling insulating layer.

Forming of the crystalline charge trap layer may include forming an amorphous charge trap layer on the tunneling insulating layer; and crystallizing the amorphous charge trap layer to form the crystalline charge trap layer.

Here, the crystallizing of the amorphous charge trap layer may be performed by ion implantation.

The amorphous charge tap layer may include an amorphous silicon nitride, and the ion implantation may be an ion N+ implantation, wherein the crystalline charge trap layer formed by the N+ ion implantation includes a crystalline silicon nitride.

The crystalline charge trap layer may be performed by high-temperature deposition. Here, the crystalline charge trap layer may include a crystalline silicon nitride.

The method of manufacturing the non-volatile memory device may further include forming a blocking insulating layer on the crystalline trap layer; and forming a gate electrode on the blocking insulating layer.

According to the non-volatile material device of the present invention, a charge trap layer has a crystalline structure so that charge carriers can be trapped at a specific defect energy level. Therefore, disadvantages of an amorphous charge trap layer, such as charge leakage and an operating speed decrease caused by an extended band tail, can be prevented.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a non-volatile memory device according to an embodiment of the present invention;

FIG. 2A is a view illustrating vertical distribution of charge carriers (electrons and holes) stored in an amorphous silicon nitride layer;

FIG. 2B illustrates a threshold voltage variation versus time of memory devices including amorphous silicon nitride layers having different silicon/nitrogen composition ratios;

FIG. 3 is a graph illustrating density of state (DOS) of an amorphous silicon nitride layer;

FIG. 4 is a graph illustrating DOS of a crystalline silicon nitride layer;

FIG. 5 is a schematic view illustrating N+ ion implantation used for changing the structure of a silicon nitride layer from amorphous into crystalline according to an embodiment of the present invention; and

FIG. 6 illustrates an X-ray diffraction (XRD) of a crystalline silicon nitride layer formed by N+ ion implantation.

### DETAILED DESCRIPTION OF THE INVENTION

A non-volatile memory device and a method of manufacturing the non-volatile memory device will now be described more fully with reference to the accompanying drawings, in which exemplary embodiments of the invention are shown.

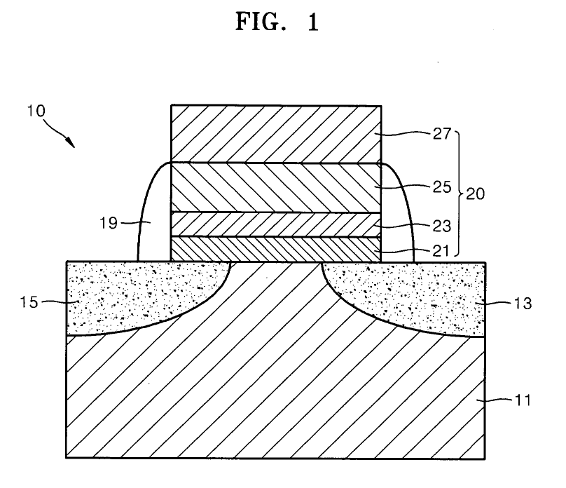

FIG. 1 is a schematic view illustrating a non-volatile memory device 10 according to an embodiment of the present invention. The non-volatile memory device 10 includes a substrate 11 and a gate structure 20 formed on the substrate 11. The substrate 11 may include first and second impurity regions 13 and 15 doped with a predetermined conductive impurity. For example, the first and second impurity regions 13 and 15 can be N+ doped regions. One of the first and second impurity regions 13 and 15 can be used as a drain (D), and the other can be used as a source (S).

The gate structure 20 includes a tunneling insulating layer 21 formed on the substrate 11, a charge trap layer 23 formed on the tunneling insulating layer 21, and a blocking insulating layer 25 formed on the charge trap layer 23. A control gate electrode 27 can be formed on the blocking insulating layer 25. Reference numeral 19 denotes a spacer.

The tunneling insulating layer 21 is formed on the substrate 11 for tunneling charge carriers. The tunneling insulating layer 21 is electrically connected to the first and second impurity regions 13 and 15. The tunneling insulating layer 21 can be a tunneling oxide layer. For example, the tunneling insulating layer 21 can be formed of a silicon oxide (SiO₂), a high-permittivity (high-k) oxide, or a combination thereof.

Alternatively, the tunneling insulating layer 21 can be formed of a silicon nitride such as Si₃N₄. In this case, the tunneling insulating layer 21 can be formed of a silicon nitride layer having good interfacial characteristics with respect to silicon and a low impurity concentration (i.e., a low impurity concentration substantially equivalent to that of a silicon oxide layer). For this, the tunneling insulating layer 21 can be formed of a silicon nitride by a special method such as jet vapor deposition.

Alternatively, the tunneling insulating layer 21 can have a double-layer structure including a silicon nitride layer and an oxide layer.

As explained above, the tunneling insulating layer 21 can have a single layer structure including a nitride layer or an oxide layer, or a multi-layer structure formed of materials having different energy band gaps.

The charge trap layer 23 is used to store information (i.e., data). In the non-volatile memory device 10 of the current embodiment, the charge trap layer 23 may include a crystalline material.

The charge trap layer 23 can be configured to stores information by trapping charge carriers. In this case, the non-volatile memory device 10 is a charge-trap memory device, and the charge trap layer 23 may be formed using a crystalline nitride or a crystalline high-k insulating material.

A nitride such as a crystalline silicon nitride (SiₓN_{y}) can be used for forming the charge trap layer 23. In this case, the crystalline silicon nitride may have a silicon/nitrogen composition ratio in the following range: 0.75≦x/y≦0.9, where x denotes silicon content, and y denotes nitrogen content. For example, when the crystalline silicon nitride has a silicon/nitride composition ratio of x/y=0.75, the crystalline silicon nitride may be Si₃N₄.

High-k insulating materials that can be used for forming the charge trap layer 23 can be at least one of high-k oxides such as crystalline SiO₂, HfO₂, ZrO₂, Al₂O₃, HfSiON, HfON, and HfAlO. High-k oxides that can be used for forming the charge trap layer 23 can be changed a composition ratio within an allowable range.

The blocking insulating layer 25, which prevents the charge carriers from passing through the charge trap layer 23 and moving upwards, may be formed of an oxide layer. For example, the blocking insulating layer 25 may be formed of a high-k material such as aluminum oxide (Al₂O₃) layer.

The blocking insulating layer 25 may be formed of SiO₂ or a high-k material having permittivity higher than that of the tunneling insulating layer 21. Examples of high-k materials that can be used for forming the blocking insulating layer 25 include SiON, Si₃N₄, HfO₂, Ta₂O₅, ZrO₂, TiO₂, La₂O₃, ScxOy, lanthanide oxide, and combinations thereof. The blocking insulating layer 25 can may a multi-layer structure. For example, the blocking insulating layer 25 can have a two or more layer structure including an insulating layer formed of a generally used insulation material such as SiO₂ and a high-k layer having permittivity higher than that of the tunneling insulating layer 21.

The control gate electrode 27 may be formed of a metal layer. For example, the control gate electrode 27 can be formed of Al, Ru, TaN or a silicide such NiSi.

As described above, in the present embodiment, the charge trap layer 23 of the non-volatile memory device 10 has a crystalline structure. Therefore, a band tail does not extend in the charge trap layer 23, and thus charge carriers can be trapped only at a specific defect level (this will be described later in detail). Thus, as compared with an amorphous charge trap layer, the crystalline charge trap layer 23 of the present embodiment does not result in charge leakage and a decrease in operating speed since an extended band tail does not generate in the crystalline charge trap layer.

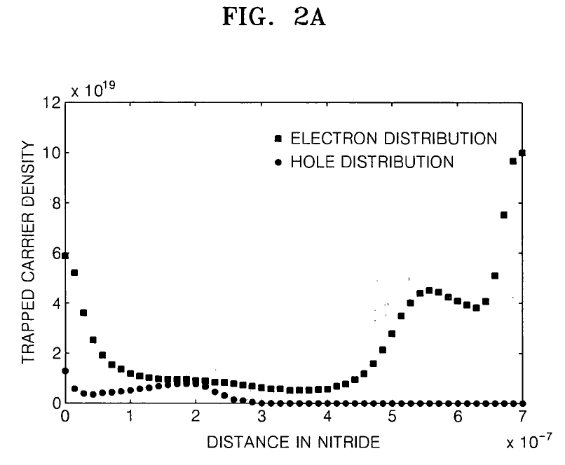

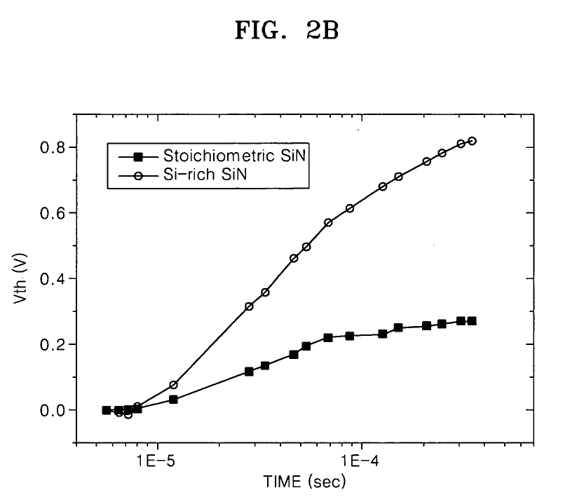

FIG. 2A is a view illustrating vertical distribution of charge carriers (electrons and holes) stored in an amorphous silicon nitride layer, and FIG. 2B is a threshold voltage variation versus time graph of memory devices including amorphous silicon nitride layers having different silicon/nitrogen composition ratios. FIG. 2B illustrates threshold voltage variation according to time in a memory device having a stoichiometric SiN layer, and threshold voltage variation according to time in a memory device having a Si-rich SiN layer in which silicon is rich relative to nitrogen. In FIG. 2A, the horizontal axis denotes a distance in the amorphous silicon nitride layer from a tunneling insulating layer, and as it goes to the right, a blocking insulating layer is approached. The vertical axis of FIG. 2A denotes a trapped carrier density. In FIG. 2B, the horizontal axis denotes time in seconds, and the vertical axis denotes a threshold voltage Vth. In FIG. 2B, variations of the threshold voltage were measured with respect to time without applying an external bias voltage.

Referring to FIG. 2A, charge carriers stored in an amorphous charge trap layer are non-uniformly distributed in a vertical direction. Particularly, electrons are much non-uniformly distributed. Therefore, after writing/erasing operations, the threshold voltage may become unstable. That is, the threshold voltage may vary largely with time as shown in FIG. 2B. The variation of the threshold voltage is largely dependent on the silicon/nitrogen composition ratio of the amorphous silicon nitride layer. In the case of the Si-rich SiN layer in which silicon is rich relative to nitrogen, the threshold voltage varies further greatly with respect to time due to a lot of shallow traps.

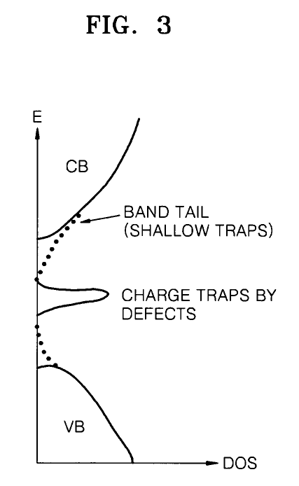

Such variations of the threshold voltage are caused by an extended band tail of the amorphous silicon nitride layer as shown in FIG. 3. The variations of the threshold voltage shown in FIG. 2B explain the fact that electron distribution changes due to shallow traps caused by a band tail.

FIG. 3 illustrates density of state (DOS) of an amorphous silicon nitride layer.

As shown in FIG. 3, in the case of an amorphous silicon nitride layer, band tails are present between the conductive band (CB) and the valence band (VB). The band tails extend to a defect level at which charge carriers are trapped.

Due to the extended band tails, the charge carriers trapped in the defect level are easily released from the defect level, and it takes much time to stabilize the threshold voltage during writing/erasing operations.

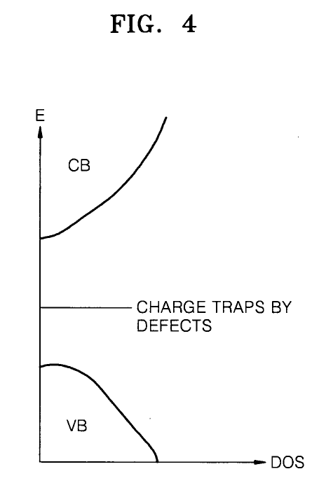

However, referring to FIG. 4, in the case of a crystalline silicon nitride layer, no extended band tail is present, and thus electric carriers can be trapped at a detect level more stably. FIG. 4 illustrates DOS of a crystalline silicon nitride layer.

As described above, to be present no extended band tail in a crystalline silicon trap layer. In the present invention, the charge trap layer 23 of the non-volatile memory device 10 may be formed into a crystalline structure by various methods such as ion implantation or high-temperature deposition.

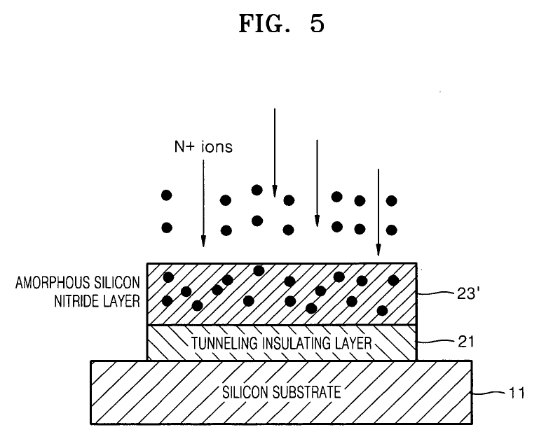

In a method of manufacturing a non-volatile memory device according to an embodiment of the present invention, a tunneling insulating layer 21 is formed on a substrate 11 such as a silicon substrate, and an amorphous charge trap layer 23′ such as an amorphous silicon nitride layer is formed on the tunneling insulating layer 21 as shown in FIG. 5. Then, ion implantation may be performed on the amorphous charge trap layer 23′ to change the structure of the amorphous charge trap layer 23′ from amorphous into crystalline. In this way, a crystalline charge trap layer 23 may be formed. After the ion implantation, heat treatment may be additionally performed. When the amorphous charge trap layer 23′ is an amorphous silicon nitride layer, N+ ion implantation may be performed to change the structure of the amorphous silicon nitride layer from amorphous into crystalline.

When forming the crystalline charge trap layer 23 from the amorphous charge trap layer 23′ through the ion implantation, an ion material may be selected depending on the material used to form the charge trap layer.

In another embodiment, a crystalline charge trap layer 23 may be formed on a tunneling insulating layer 21 by high-temperature deposition.

As described above, in the method of manufacturing a non-volatile memory device, the tunneling insulating layer 21 is formed on the substrate 11, and then the crystalline charge trap layer 23 is formed on the tunneling insulating layer 21 through various methods such as ion implantation or high-temperature deposition. Thereafter, a blocking insulating layer 25 is formed on the crystalline charge trap layer 23, and a gate electrode 27 is formed on the blocking insulating layer 25. Then, first and second impurity regions 13 and 15 electrically connected to the tunneling insulating layer 21 are formed in the substrate 11. In this way, the non-volatile memory device 10 shown in FIG. 1 may be manufactured according to an embodiment of the present invention.

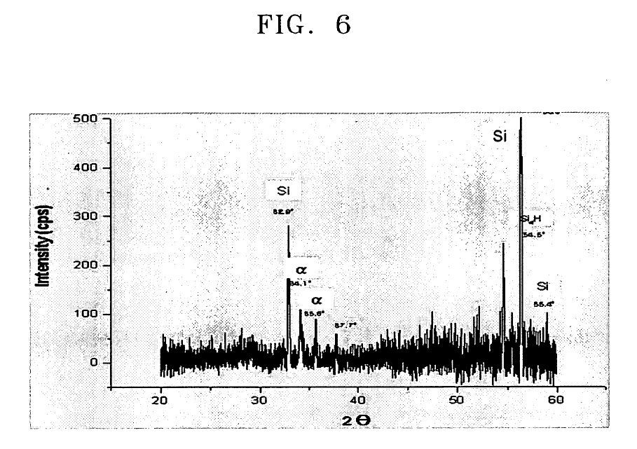

FIG. 5 is a schematic view illustrating N+ ion implantation used for changing the structure of a silicon nitride layer from amorphous into crystalline according to an embodiment of the present invention, and FIG. 6 illustrates an X-ray diffraction (XRD) of a crystalline silicon nitride layer formed by N+ ion implantation.

In FIG. 6, high peaks denoted by Si correspond to crystalline silicon and relatively low peaks denoted by β correspond to a crystalline silicon nitride (Si₃N₄). Referring to FIG. 6, peak corresponding to a tunneling insulating layer such as SiO₂ layer does not show since the SiO₂ layer is amorphous. It can be understood from FIG. 6 that a single crystal silicon substrate is used, and a charge trap layer is formed of a crystalline silicon nitride.

As explained above, when the structure of an amorphous silicon nitride layer, which is used as a charge trap layer of a charge-trap non-volatile memory device, can be changed from amorphous into crystalline to improve the characteristics of the non-volatile memory device can be improved. That is, when an amorphous silicon nitride layer is used as a charge trap layer of a charge-trap non-volatile memory device, it is difficult to keep charge carriers at a defect level due to an extended band tail. Furthermore, it is also difficult to rapidly stabilize the threshold voltage of the charge-trap non-volatile memory device after writing/erasing operations. That is, although discontinuous traps are used, the characteristics of the memory device may deteriorate unexpectedly if an amorphous silicon nitride layer is used as a charge trap layer.

However, when a crystalline silicon nitride layer is used as a charge trap layer of a charge-trap non-volatile memory device, charge carriers can be stably trapped at a defect level since no extended band tail is present in the charge trap layer, and a stable threshold voltage can be rapidly obtained. Therefore, the characteristics of the memory device can improve. For example, the writing/erasing characteristics of the memory device can improve, and the reliability of the memory device can increase.

In the above-described embodiment, the charge trap layer of the non-volatile memory device is formed of a crystalline silicon nitride layer. However, the present invention is not limited thereto. An amorphous material has problem regarding a band tail. Thus, although the charge trap layer of the non-volatile memory device is formed of various materials except a silicon nitride, the structure of the charge trap layer can be changed from amorphous into crystalline using a method such as ion implantation and high-temperature deposition, and thus a crystalline charge trap later being formed of at least any one of various materials and having no band tail can be obtained. That is, in the present invention, the charge trap layer of the nonvolatile memory device can be formed of at least one of various materials including a silicon nitride.

Furthermore, in the above-described embodiment, the crystalline charge trap layer is formed by ion implantation or high-temperature deposition. However, the present invention is not limited thereto. That is, other various methods can be used to form the crystalline charge trap layer.

Moreover, in the above-described embodiments, the non-volatile memory device is a charge-trap memory device. However, the present invention is not limited thereto. That is, the present invention can be applied to other memory devices using a crystalline charge trap layer.

What is claimed is:

1. A non-volatile memory device comprising:
a substrate; and
a gate structure formed on the substrate and comprising a charge trap layer, the charge trap layer comprising a crystalline material.

2. The non-volatile memory device of claim 1, wherein the gate structure further comprises:
a tunneling insulating layer under the charge trap layer;
a blocking insulating layer formed on the charge trap layer; and
a gate electrode formed on the blocking insulating layer.

3. The non-volatile memory device of claim 2, further comprising first and second impurity regions formed in the substrate in contact with the tunneling insulating layer.

4. The non-volatile memory device of claim 2, wherein the substrate is a silicon substrate, the tunneling insulating layer is a silicon oxide layer, the blocking insulating layer is an aluminum oxide layer, and the gate electrode is a metal layer.

5. The non-volatile memory device of claim 4, wherein the gate electrode comprises a TaN layer.

6. The non-volatile memory device of claim 4, wherein the charge trap layer comprises a crystalline silicon nitride.

7. The non-volatile memory device of claim 6, wherein the crystalline silicon nitride has a silicon/nitrogen composition ratio in the following range:
0.75≦x/y≦0.9
where x denotes silicon content, and y denotes nitrogen content.

8. The non-volatile memory device of claim 6, wherein the gate electrode comprises a TaN layer.

9. The non-volatile memory device of claim 1, wherein the charge trap layer comprises a crystalline silicon nitride layer.

10. The non-volatile memory device of claim 9, wherein the crystalline silicon nitride has a silicon/nitrogen composition ratio in the following range:
0.75≦x/y≦0.9
where x denotes silicon content, and y denotes nitrogen content.

11. A method of manufacturing a non-volatile memory device, the method comprising:
forming a tunneling insulating layer on a substrate; and
forming a crystalline charge trap layer on the tunneling insulating layer.

12. The method of claim 11, wherein the forming of the crystalline charge trap layer comprises:
forming an amorphous charge trap layer on the tunneling insulating layer; and
crystallizing the amorphous charge trap layer to form the crystalline charge trap layer.

13. The method of claim 12, wherein the crystallizing of the amorphous charge trap layer is performed by ion implantation.

14. The method of claim 13, wherein the amorphous charge trap layer comprises an amorphous silicon nitride, and the ion implantation is N+ ion implantation,
wherein the crystalline charge trap layer formed by the N+ ion implantation comprises a crystalline silicon nitride.

15. The method of claim 14, wherein the crystalline silicon nitride forming the crystalline charge trap layer has a silicon/nitrogen composition ratio in the following range:
0.75≦x/y≦0.9
where x denotes silicon content, and y denotes nitrogen content.

16. The method of claim 11, wherein the forming of the crystalline charge trap layer is performed by high-temperature deposition.

17. The method of claim 16, wherein the crystalline charge trap layer comprises a crystalline silicon nitride.

18. The method of claim 17, wherein the crystalline silicon nitride has a silicon/nitrogen composition ratio in the following range:
0.75≦x/y≦0.9
where x denotes silicon content, and y denotes nitrogen content.

19. The method of claim 11, further comprising:
forming a blocking insulating layer on the crystalline trap layer; and
forming a gate electrode on the blocking insulating layer.

20. The method of claim 19, wherein the substrate is a silicon substrate, the tunneling insulating layer is a silicon oxide layer, the blocking insulating layer is an aluminum oxide layer, and the gate electrode is a metal layer.

21. The method of claim 20, wherein the gate electrode comprises a TaN layer.
